(19) United States
(12) Patent Application Publication
(10) Pub. No.: US 2015/0184289 A1
(43) Pub. Date: Jul. 2, 2015

(54) DEPOSITION APPARATUS AND DEPOSITION METHOD

(71) Applicant: Samsung Display Co., Ltd., Yongin-City (KR)

(72) Inventors: Yong Suk LEE, Suwon-si (KR); Suk Won JUNG, Seoul (KR); Myung Soo HUH, Suwon-si (KR)

(21) Appl. No.: 14/468,042

(22) Filed: Aug. 25, 2014

(30) Foreign Application Priority Data
Dec. 30, 2013 (KR) 10-2013-0167560

(51) Int. Cl. C23C 16/44; C23C 16/52

(52) U.S. Cl. CPC C23C 16/4402; C23C 16/4408; C23C 16/52

(57) ABSTRACT

An apparatus may be used for forming a material layer on a substrate. The apparatus may include a reactor that includes a supply unit set configured to supply a material to the substrate. The apparatus may further include a control mechanism configured to control whether the material is provided to the supply unit set according to a position of the substrate with respect to the reactor.

### CROSS-REFERENCE TO RELATED APPLICATION

This application claims priority to and the benefit of Korean Patent Application No. 10-2013-0167560 filed in the Korean Intellectual Property Office on Dec. 30, 2013, the entire contents of which are incorporated herein by reference.

### BACKGROUND

(a) Field

The present invention relates to a deposition apparatus, e.g., an atomic layer deposition apparatus, and a related deposition method.

(b) Description of the Related Art

A conventional deposition apparatus, e.g., a conventional atomic layer deposition apparatus, may include at least one reactor for deposition of a material layer (e.g., an atomic layer) on a substrate. The substrate may be exposed to one or more chemical materials, such as one or more of a source precursor, a purge gas, and a reactant precursor, when the substrate passes through the reactor(s).

A source precursor molecule deposited to the substrate may react with a reactant precursor molecule, or the source precursor molecule may be substituted by the reactant precursor molecule, such that the material layer may be formed on the substrate. After the substrate is exposed to the source precursor or the reactant precursor, the substrate may be exposed to a purge gas so as to eliminate the source precursor molecule, the reactant precursor molecule, or a related product from the substrate.

The above information disclosed in this Background section is for enhancement of understanding of the background of the invention. This Background section may contain information that does not form the prior art that is already known in this country to a person of ordinary skill in the art.

### SUMMARY

Embodiments of the present invention may be related to a deposition apparatus, e.g., an atomic layer deposition apparatus, capable of substantially preventing or minimizing excessive and/or ineffective use of materials, such as one or more of a source precursor, a reactant precursor, and a purge gas, in a process for forming a material layer on a substrate. The deposition apparatus may additionally or alternatively prevent potential formation and/or deposition of unwanted particles. Embodiments of the invention may be related to a deposition method, e.g., an atomic layer deposition method, performed using the deposition method.

An embodiment of the present invention may be related to an apparatus for forming a material layer on a substrate. The apparatus may include a reactor that includes a supply unit set configured to supply at least a first supply material to the substrate. The apparatus may further include a control mechanism configured to control whether the first supply material is provided to the supply unit set according to a position of the substrate with respect to the reactor.

The apparatus may include a first supply valve connected to the supply unit set. The control mechanism may control the first supply valve to start providing the first supply material to the supply unit set when a first end of the substrate overlaps the reactor and when a second end of the substrate does not overlap the reactor.

The control mechanism may control the first supply valve to start providing the first supply material to the supply unit set when or after the first end of the substrate moves relative to the reactor in a first direction to overlap a first portion of the reactor. The control mechanism may further control the first supply valve to start providing the first supply material to the supply unit set when or after the second end of the substrate moves relative to the reactor in a second direction to overlap a second portion of the reactor, The second direction is opposite to the first direction.

The control mechanism may control the first supply valve to stop providing the first supply material to the supply unit set when or after the second end of the substrate moves relative to the reactor in a first direction past a portion of the reactor and when the first end of the substrate does not overlap the reactor. The control mechanism may further control the first supply valve to start providing the first supply material to the supply unit set when or after the second end of the substrate moves relative to the reactor in a second direction to overlap the portion of the reactor, The second direction is opposite to the first direction.

The control mechanism may control the first supply valve to stop providing the first supply material to the supply unit set when the second end of the substrate overlaps a portion of the reactor and when the first end of the substrate does not overlap the reactor.

The reactor may further include a suction unit set configured to suction a least a first residual material from a chamber, which may contain the substrate. The control mechanism may further control whether the suction unit set suctions the first residual material from the chamber according to the position of the substrate with respect to the reactor.

The apparatus may include a pump connected to the suction unit set. The control mechanism may turn off the pump to prevent the suction unit set from performing suction when a first end of the substrate overlaps the reactor and when a second end of the substrate does not overlap the reactor.

The control mechanism may turn off the pump when or after the first end of the substrate moves relative to the reactor in a first direction to overlap a portion of the reactor. The control mechanism may further turn on the pump when or after the first end of the substrate moves relative to the reactor in a second direction past the portion of the reactor. The second direction may be opposite to the first direction.

The control mechanism may turn on the pump to enable the suction unit set to suction the first residual material when or after the second end of the substrate moves relative to the reactor in a first direction past a portion of the reactor and when the first end of the substrate does not overlap the reactor. The control mechanism may further turn off the pump when or after the second end of the substrate moves relative to the reactor in a second direction to overlap the portion of the reactor and when the first end of the substrate does not overlap the reactor. The second direction is opposite to the first direction.

The control mechanism may turn on the pump to enable the suction unit set to suction the first residual material when the second end of the substrate overlaps a portion of the reactor and when the first end of the substrate does not overlap the reactor.

The supply unit set may include a first supply unit for supplying a first supply material, a second supply unit for supplying a second supply material, and a third supply unit for supplying a purge gas. The third supply unit may be disposed between the first supply unit and the second supply unit. The suction unit set may include a first suction unit and a second suction unit. The first suction unit may be disposed between the first supply unit and the third supply unit and may suction a first portion of the first residual material. The second suction unit may be disposed between the second supply unit and the third supply unit and may suction a second portion of the first residual material.

An embodiment of the present invention may be related to an apparatus for forming a material layer on a substrate. The apparatus may include a chamber for containing the substrate. The apparatus may further include a reactor that includes a supply unit set and a suction unit set. The supply unit set may supply at least a first supply material to the substrate. The suction unit set may suction a least a first residual material from the chamber. The apparatus may further include a control mechanism. The control mechanism may start supply of the first supply material to the supply unit set when or after a first end of the substrate moves relative to the reactor in a direction to overlap the reactor and when a second end of the substrate does not overlap the reactor. The control mechanism may stop the suction unit set from performing suction when or after the first end of the substrate moves relative to the reactor in the direction to overlap the reactor and when the second end of the substrate does not overlap the reactor.

An embodiment of the present invention may be related to a method for forming a material layer on a substrate. The method may include the following steps: performing relative movement between the substrate and a reactor; and controlling whether to supply a first supply material to the substrate according to a position of the substrate with respect to the reactor.

The method may include the following steps: starting supplying the first supply material to the substrate when or after a first end of the substrate moves relative to the reactor in a first direction to overlap a first portion of the reactor and when a second end of the substrate does not overlap the reactor; and stop supplying the first supply material to the substrate when or after the second end of the substrate moves relative to the reactor in the first direction past a second portion of the reactor and when the first end of the substrate does not overlap the reactor.

The method may further include the following steps: starting supplying the first supply material to the substrate when or after the second end of the substrate moves relative to the reactor in a second direction to overlap the second portion of the reactor and when the first end of the substrate does not overlap the reactor, The second direction is opposite to the first direction; and stop supplying the first supply material to the substrate when or after the first end of the substrate moves relative to the reactor in the second direction past the first portion of the reactor and when the second end of the substrate does not overlap the reactor.

The method may include the following steps: supplying the first supply material into a chamber that contains the substrate; and starting suctioning a first residual material from the chamber when or after the second end of the substrate moves relative to the reactor in the first direction past the second portion of the reactor and when the first end of the substrate does not overlap the reactor.

An embodiment of the present invention may be related to an atomic layer deposition apparatus that may include the following elements: a reactor for supplying a source precursor and a reactant precursor to a substrate and for suctioning a residual source precursor and a residual reactant precursor from the substrate and/or from a chamber, which may contain the substrate; a supply valve set for blocking supply of the source precursor and supply of the reactant precursor to the reactor; an exhaust valve for blocking exhaust of the residual source precursor and the residual reactant precursor suctioned by the reactor; a valve controller for opening and closing the supply valve and the exhaust valve, respectively; a carrier (e.g., a susceptor) to which the substrate is mounted, which may slide in opposite directions along a path that is perpendicular to a direction in which the source precursor and the reactant precursor are supplied; and a main controller connected to the valve controller for controlling the valve controller according to a location of the substrate with respect to the reactor.

The main controller may close the supply valve and close the exhaust valve when one end of the substrate (which is provided on the susceptor) overlaps the reactor. The main controller may close the supply valve and open the exhaust valve when the other end of the substrate (which is mounted on the susceptor) has passed the reactor and thus does not overlap the reactor.

The atomic layer deposition apparatus may further include an exhaust unit connected to the reactor for exhausting the residual source precursor and the residual reactant precursor.

The exhaust valve may be provided between the exhaust unit and the reactor.

The exhaust unit includes an exhaust path through which the residual source precursor and the residual reactant precursor are transmitted. The exhaust unit further includes an exhaust pump connected to the exhaust path for exhausting the residual source precursor and the residual reactant precursor.

The main controller may turn off the exhaust pump when one end of the substrate mounted to the sliding susceptor overlaps the reactor. The main controller may turn on the exhaust pump when the other end of the substrate mounted to the sliding susceptor passes the reactor and thus does not overlap the reactor.

The atomic layer deposition apparatus may further include a source supply unit connected with the reactor for supplying the source precursor and the reactant precursor to the reactor.

The supply valve set may be provided between the source supply unit and the reactor.

The atomic layer deposition apparatus may further include a driver for driving linear motion of the susceptor.

The main controller may be connected to the driver and may sense a location of the susceptor with respect to the reactor.

The reactor may supply a purge gas to the substrate.

The supply valve set may block supply of the purge gas with respect to the reactor.

The supply valve set may include the following valves: a first valve for blocking supply of the source precursor; a second valve for blocking supply of the reactant precursor; and a third valve for blocking supply of the purge gas.

The reactor may include the following elements: a first supply unit supplying the source precursor to the substrate; a second supply unit supplying the reactant precursor to the substrate; a third supply unit supplying the purge gas to the substrate; and a suction unit suctioning the source precursor and the reactant precursor.

The first supply unit, the second supply unit, the third supply unit, and the suction unit may each include a plurality of units.

The first supply unit, a first unit of the third supply unit, the second supply unit, and a second unit of the third supply unit may be sequentially arranged in that order. A first unit of the suction unit may be provided between the first supply unit and the first unit of the third supply unit. A second unit of the suction unit may be provided between the second unit of the third supply unit and the second supply unit.

An embodiment of the present invention may be related to a deposition method, e.g., an atomic layer deposition method. The method may be performed using an atomic layer deposition apparatus that includes a reactor for supplying a source precursor and a reactant precursor to a sliding substrate and for suctioning a residual source precursor and a residual reactant precursor from the substrate and/or from a chamber, which may contain the substrate. The deposition method may include controlling at least one of the supplying and the suctioning according to a location of the substrate with respect to the reactor.

In the method, the supplying may be performed, and the suctioning may not be performed, when one end of the sliding substrate overlaps the reactor. The supplying may not be performed, and the suctioning may be performed, when the other end of the sliding substrate passes the reactor and thus does not overlap the reactor.

The suctioning may be performed using a suction pump.

The atomic layer deposition method may include sensing a location of the substrate with respect to the reactor.

### BRIEF DESCRIPTION OF THE DRAWINGS

FIG. 1 shows a schematic diagram that illustrates a deposition apparatus, e.g., an atomic layer deposition apparatus, according to an embodiment of the present invention.

FIG. 2 shows a schematic diagram that illustrates a reactor, a substrate, a driver, and a main controller illustrated in FIG. 1.

FIG. 3, FIG. 4, and FIG. 5 show schematic diagrams that illustrate a deposition method, e.g., an atomic layer deposition method, according to an embodiment of the present invention.

### DETAILED DESCRIPTION

Embodiments of the present invention will be described more fully hereinafter with reference to the accompanying drawings. As those skilled in the art would realize, the described embodiments may be modified in various different ways, all without departing from the spirit or scope of the present invention.

The drawings and description are illustrative and not restrictive. Like reference numerals may designate like elements in the specification. Repetition of description may be avoided.

The relative sizes and thicknesses of elements shown in the drawings are for facilitate description and understanding, without limiting the present invention.

In the drawings, the thicknesses of some layers, films, panels, regions, etc., may be exaggerated for clarity.

In the description, if an element (such as a layer, film, region, or substrate) is referred to as being “on” another element, it can be directly on the other element, or an intervening element may also be present.

Unless explicitly described to the contrary, the word “comprise” and variations such as “comprises”, “comprising”, “include”, or “including” may imply the inclusion of stated elements but not the exclusion of other elements.

The word “on” may mean being positioned above or below, but may not be limited to being positioned above or on an upper side according to a gravity direction.

Although the terms “first”, “second”, etc. may be used herein to describe various elements, these elements, should not be limited by these terms. These terms may be used to distinguish one element from another element. Thus, a first element discussed below may be termed a second element without departing from the teachings of the present invention. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Various embodiments, including methods and techniques, are described in this disclosure. It should be kept in mind that the invention might also cover an article of manufacture that includes a non-transitory computer readable medium on which computer-readable instructions for carrying out embodiments of the inventive technique are stored. The computer readable medium may include, for example, semiconductor, magnetic, opto-magnetic, optical, or other forms of computer readable medium for storing computer readable code. Further, the invention may also cover apparatuses for practicing embodiments of the invention. Such apparatus may include circuits, dedicated and/or programmable, to carry out operations pertaining to embodiments of the invention. Examples of such apparatus include a general purpose computer and/or a dedicated computing device when appropriately programmed and may include a combination of a computer/computing device and dedicated/programmable hardware circuits (such as electrical, mechanical, and/or optical circuits) adapted for the various operations pertaining to embodiments of the invention.

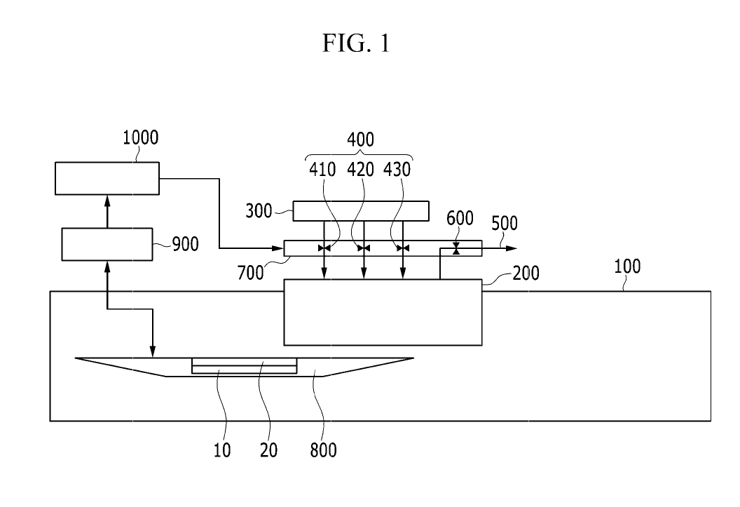

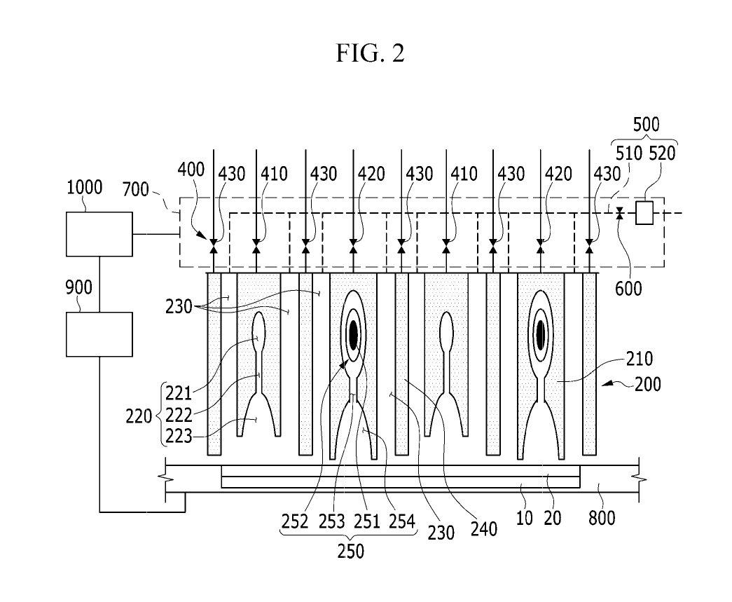

FIG. 1 shows a schematic diagram that illustrates a deposition apparatus, e.g., an atomic layer deposition apparatus, according to an embodiment of the present invention. FIG. 2 shows a schematic diagram that illustrates a reactor, a substrate, a driver, and a main controller illustrated in FIG. 1.

As shown in FIG. 1 and FIG. 2, the atomic layer deposition apparatus may be used for deposition of a material layer to a substrate 10. In an embodiment, the material layer may be a thin film encapsulation layer of an organic light emitting apparatus.

The atomic layer deposition apparatus includes a chamber 100, a reactor 200, a source supply unit 300, a supply valve set 400, an exhaust unit 500, an exhaust valve 600, a valve controller 700, a carrier 800 (e.g., a susceptor 800), a driver 900, and a main controller 1000.

The chamber 100 may be closed, may be sealed, and may be connected to a vacuum pump for forming a vacuum inside of the chamber 100. Internal pressure and temperature of the chamber 100 may be controlled, and various units that control the internal pressure and temperature of the chamber 100 may be connected to the chamber 100. The chamber 100 may have a sufficient sliding space so as to allow the susceptor 800 to slide in the space, e.g., to the left side and to the right side of the chamber 100 illustrated in FIG. 1.

The reactor 200 may supply a source precursor, a reactant precursor, and a purge gas to the substrate 10. The reactor 200 may suction a residual source precursor, a residual reactant precursor, and a residual purge gas from the substrate 10 and/or from the chamber 100. As shown in FIG. 2, the reactor 200 includes a main body 210, a first-type supply unit 220 (or first supply unit 220) for supplying the source precursor to the substrate 10, a second-type supply unit 250 (or second supply unit 250) for supplying the reactant precursor to the substrate 10, a third-type supply unit 240 (or third supply unit 240) for supplying the purge gas to the substrate 10, and a suction unit 230 for suctioning the residual source precursor, the residual reactant precursor, and the residual purge gas that remain on the substrate 10 and/or in the chamber 100.

The first supply unit 220 includes a channel 221, a first perforation 222, and a first chamber 223, and is formed in the main body 210. The source precursor supplied from the source supply unit 300 may be provided to the first chamber 223 through the channel 221 and the first perforation 222 and then supplied to the substrate 10. The source precursor supplied to the substrate 10 may be adsorbed by the substrate 10.

The reactor 200 may include a plurality of first supply units 220, and first supply units 220 may be separated from each other.

In an embodiment of the present invention, the source precursor may be trimethylaluminum (TMA). In an embodiment, the source precursor may be or may include one or more of various source precursor materials.

The second supply unit 250 includes a radical chamber 252, an electrode 251, a second perforation 253, and a second chamber 254 and is formed in the main body 210. When voltages of different levels are respectively applied to the main body 210 and the electrode 251, plasma may be generated in the radical chamber 252 and thus a radical of the reactant precursor supplied in the radical chamber 252 may be generated. The radical of the reactant precursor, generated in the radical chamber 252, may be provided to the second chamber 254 through the second perforation 253 and then supplied to the substrate 10. The radical of the reactant precursor, supplied to the substrate 10, may react with the source precursor adsorbed by the substrate 10 or may substitute the source precursor. Accordingly, a material layer may be formed on the substrate 10.

The reactor 200 may include a plurality of second supply units 250, and the second supply units 250 may be separated from each other and may be respectively disposed between neighboring first supply units 220. In an embodiment of the present invention, the radical of the reactant precursor may be an oxygen radical. In an embodiment, the reactant precursor may be or may include at least a precursor for one or more of various reactions.

A plurality of third supply units 240 may supply the purge gas to the substrate 10. Some third supply units 240 may be positioned at lateral ends of the reactor 200, and some third supply units 240 may be respectively positioned between first supply units 220 and second supply units 250. The purge gas supplied to the substrate 10 through the third supply units 240 may separate the residual source precursor and the residual reactant precursor from the substrate 10. The supply units 220, 250, and 240 may be (e.g., individually, separately, and/or sectionally) controlled to substantially prevent the source precursor, the reactant precursor, and the purge gas from being provided beyond an area where the substrate 10 overlaps the reactor 200, thereby preventing or minimizing waste of materials. In an embodiment, the purge gas may be argon (Ar) gas. In an embodiment, the purge gas may be or may include one or more inert gases.

The reactor 200 may include a plurality of suction units 230. The suction units 230 are respectively provided between the first supply units 220 and the third supply units 240 and/or between the third supply units 240 and the second supply units 250. The suction units 230 may suction a residual source precursor, a residual reactant precursor, and a residual purge gas that remain on the substrate 10. The residual source precursor, the residual reactant precursor, and the residual purge gas suctioned by the suction unit 230 may be exhausted outside the deposition apparatus through the exhaust unit 500.

Referring to FIG. 2, a third supply unit 240, a first supply unit 220, a third supply unit 240, a second supply unit 250, and the third supply unit 240 of the reactor 200 are sequentially arranged from the left side of the reactor 200, and suction units 230 are provided between each two of the supply units. According to embodiments of the invention, the high-density suction units 230 may enable efficient suction and discharge of the residual source precursor, the residual reactant precursor, and the residual purge gas.

The source supply unit 300 is connected with the reactor 200 and may supply the source precursor, the reactant precursor, and the purge gas to the reactor 200. The source supply unit 300 may include a plurality of supply units for separately supplying the source precursor, the reactant precursor, and the purge gas to the reactor 200.

The supply valve set 400 is provided between the source supply unit 300 and the reactor 200 and may control (e.g., block or allow) supply of the source precursor, the reactant precursor, and the purge gas from the source supply unit 300 to the reactor 200. The valve controller 700 may control opening and closing of valves of the supply valve set 400. The supply valve set 400 includes a first valve 410 for controlling supply of the source precursor to the reactor 200 from the source supply unit 300, a second valve 420 for controlling supply of the reactant precursor to the reactor 200 from the source supply unit 300, and a third valve 430 for controlling supply of the purge gas to the reactor 200 from the source supply unit 300.

The exhaust unit 500 is connected to the reactor 200 and may exhaust the residual source precursor, the residual reactant precursor, and the residual purge gas suctioned by the suction unit 230 to the outside (i.e., outside the deposition apparatus).

The exhaust unit 500 includes an exhaust path 510 and an exhaust pump 520 for respectively transmitting and exhausting the residual source precursor, the residual reactant precursor, and the residual purge gas suctioned by the suction unit 230. The exhaust path 510 may be connected between the suction units 230 and the exhaust pump 520, and the residual source precursor, the residual reactant precursor, and the residual purge gas may be exhausted to the outside through the exhaust path 510 and the exhaust pump 520.

The exhaust valve 600 is provided between the exhaust path 510 and the exhaust pump 520 and may control (e.g., block or allow) exhaust of the source precursor, the reactant precursor, and the purge gas suctioned by the suction units 230. The valve controller 700 may control opening and closing of the exhaust valve 600.

The valve controller 700 is connected to the main controller 1000, the supply valve set 400, and the exhaust valve 600 and may control opening and closing of the supply valve set 400 and the exhaust valve 600. The valve controller 700 may be controlled by the main controller 1000.

The substrate 10 is mounted to the susceptor 800, which may slide to and fro along a path that is substantially perpendicular to a direction in which the source precursor and the reactant precursor are supplied from the reactor 200. For example, in FIG. 1, the susceptor 800 may slide to and fro between the left side and the right side of the chamber 100 and may be positioned below the reactor 200, which may be disposed at a center position of the chamber 100. A mask 20 may be disposed on the substrate 10 (which is mounted on the susceptor 800), and the source precursor and the reactant precursor may be supplied from the reactor 200 through the mask 20 to the substrate 10. The susceptor 800 may include a heating unit for heating the substrate 10.

The driver 900 may control the sliding motion of the susceptor 800. The driver may include a linear motor for facilitating linear movement of the susceptor 800. The driver 900 may be controlled by the main controller 1000.

The main controller 1000 is connected to the valve controller 700, the driver 900, and the exhaust unit 500. The main controller 1000 may control opening and closing of the supply valve set 400 and the exhaust valve 600 by controlling the valve controller 700 according to a location of the substrate 10 with respect to the reactor 200 and may control on/off of the exhaust pump 520. The main controller 1000 may control the driver 900 for controlling the movement and/or location of the susceptor 800 (and the substrate 10) and may determine the location of the substrate 10 by determining the location of the susceptor 800 based on a signal received from the driver 900. In an embodiment, the main controller 1000 may be connected to a sensor that senses the location of the substrate 10. In an embodiment, the main controller 100 may be connected to one or more elements configured to sense a location of the substrate 10.

The main controller 1000 may provide control signals to the valve controller 700 to open the supply valve set 400, close the exhaust valve 600, and turn off the exhaust pump 520 when (e.g., a first end of) the substrate 10 provided in the sliding susceptor 800 substantially overlaps the reactor 200. Accordingly, the source precursor, the reactant precursor, and the purge gas are supplied to the substrate 10 from the reactor 200 such that material is deposited to form a material layer on the substrate 10.

When (e.g., a second end of) the substrate 10 provided in the sliding susceptor 800 has passed the reactor 200 and does not substantially overlap the reactor 200, the main controller 1000 may provide control signals to the valve controller 700 to close the supply valve set 400, open the exhaust valve 600, and turn on the exhaust pump 520. Accordingly, the supply of the source precursor, the reactant precursor, and the purge gas to the substrate 10 from the reactor 200 is blocked, and at the same time the residual source precursor, the residual reactant precursor, and the purge gas are exhausted to the outside through the reactor 200 and the exhaust unit 500.

According to embodiments of the present invention, supply of the source precursor, the reactant precursor, and the purge gas is blocked when the substrate 10 does not substantially overlap the reactor 200. Therefore, excessive and/or ineffective use of each of the source precursor, the reactant precursor, and the purge gas may be substantially prevented or minimized Advantageously, expenses associated with the atomic layer deposition process can be minimized.

According to embodiments of the present invention, when the substrate 10 does not substantially overlap the reactor 200, particles remaining in the reactor 200 may be prevented from being substantially reacted or substituted with either of the source precursor and the reactant precursor, so that potential formation of undesired particles in the reactor 200 may be substantially prevented, and so that potential deposition of undesired particles onto the substrate 10 can be substantially prevented when the substrate 10 overlaps the reactor 200. Advantageously, manufacturing reliability and quality of the material layer formed on the substrate 10 may be optimized.

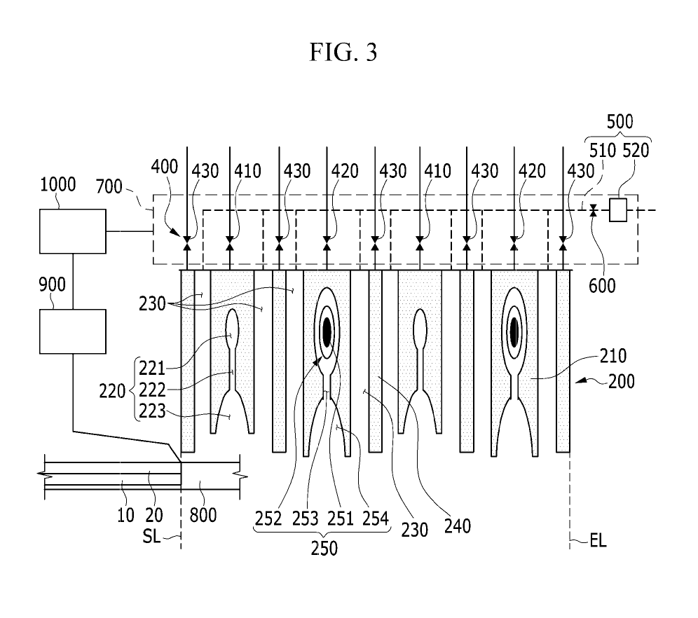

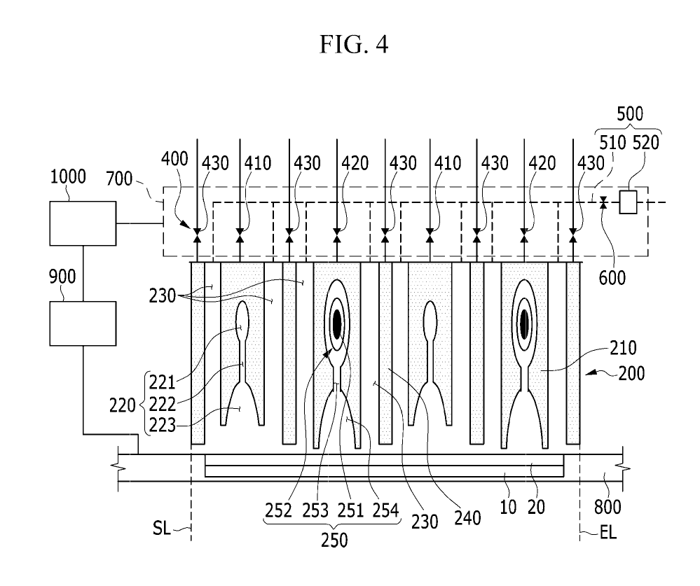

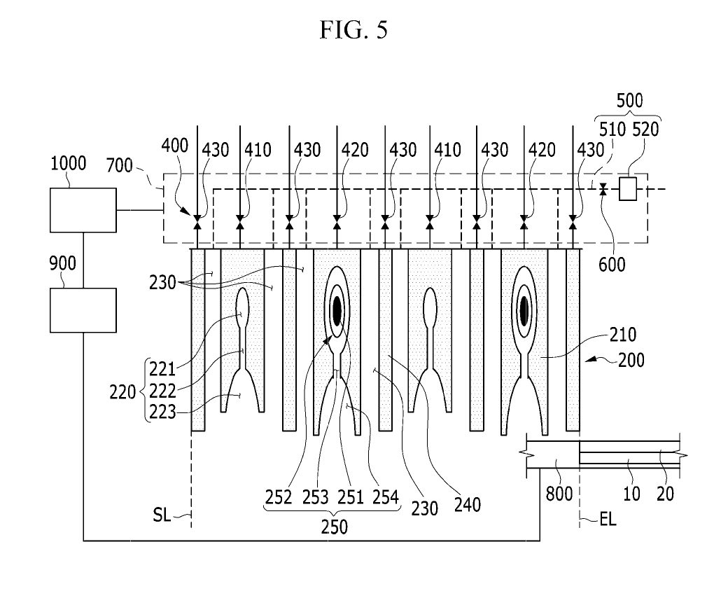

FIG. 3, FIG. 4, and FIG. 5 show schematic diagrams that illustrate a deposition method, e.g., an atomic layer deposition method, according to an embodiment of the present invention.

Referring to FIG. 3, when/after a first end (e.g., the right end) of a substrate 10 (which is mounted on a susceptor 800) slides past a first point/portion, e.g., a start terminal SL, of a reactor 200, a supply valve set 400 is opened, an exhaust valve 600 is closed, and an exhaust pump 520 is turned off, controlled by a valve controller 700 according to control signals provided by a main controller 1000. Therefore, one or more of a source precursor, a reactant precursor, and a purge gas may start to be supplied to the substrate 10, and no residual source precursor or residual reactant precursor may be suctioned. The source precursor and the reactant precursor supplied to the substrate 10 may start to form a material layer on the substrate 10.

Following the step discussed with reference to FIG. 3, referring to FIG. 4, the substrate 10 may continue to slide under the reactor 200, and the one or more of the source precursor, the reactant precursor, and the purge gas may continue to be provided to the substrate 10 before a second end (e.g., the left end) of the substrate 10 slides past a second point/portion, e.g., a termination terminal EL, of the reactor 200. Therefore, the material layer may be form on substantially the whole top surface of the substrate 10.

Following the step discussed with reference to FIG. 4, referring to FIG. 5, when/after the second end (e.g., the left end) of the substrate 10 overlaps or slides past the second point/portion, e.g., the termination terminal EL, of the reactor 200 such that the substrate does not substantially overlap the reactor 200, the supply valve set 400 is closed, the exhaust valve 600 is opened, and the exhaust pump is turned on, controlled the valve controller 700 according to control signals provided by the main controller 1000. Therefore, supply of the source precursor, the reactant precursor, and the purge gas to the substrate 10 is stopped, and suction and discharge of the residual source precursor and the residual reactant precursor are performed.

A process analogous to the process discussed with reference to FIGS. 3 to 5 may be further performed when the substrate 10 slides relative to the reactor 200 in a reverse direction. Processes analogous to the process discussed with reference to FIGS. 3 to 5 may be performed when the substrate 10 slides to and fro relative to the reactor 200 in opposite directions.

According to embodiments of the present invention, supply of the source precursor, the reactant precursor, and the purge gas to the substrate 10 is stopped or not performed when the substrate 10 does not substantially overlap the reactor 200. Therefore, excessive and/or ineffective use of the source precursor, the reactant precursor, and the purge gas may be substantially prevented or minimized Advantageously, expenses associated with the atomic layer deposition process may be minimized.

According to embodiments of the present invention, supply of the source precursor, the reactant precursor, and the purge gas is not performed when the substrate 10 does not substantially overlap the reactor 200. Therefore, particles remaining in the reactor 200 may be prevented from being substantially reacted or substituted with either of the source precursor and the reactant precursor, so that potential formation of undesired particles in the reactor 200 may be substantially prevented, and so that potential deposition of undesired particles onto the substrate 10 may be substantially prevented when the substrate 10 overlaps the reactor 200 again. Advantageously, manufacturing reliability and quality of the material layer form on the substrate 10 can be optimized.

While this invention has been described in connection with what is presently considered to be practical embodiments, it is to be understood that the invention is not limited to the disclosed embodiments. This invention is intended to cover various modifications and equivalent arrangements included within the spirit and scope of the appended claims.

What is claimed is:

1. An apparatus for forming a material layer on a substrate, the apparatus comprising:
a reactor that comprises a supply unit set configured to supply at least a first supply material to the substrate; and
a control mechanism configured to control whether the first supply material is provided to the supply unit set according to a position of the substrate with respect to the reactor.

2. The apparatus of claim 1, further comprising a first supply valve connected to the supply unit set, wherein the control mechanism is configured to control the first supply valve to start providing the first supply material to the supply unit set when a first end of the substrate overlaps the reactor and when a second end of the substrate does not overlap the reactor.

3. The apparatus of claim 2, wherein the control mechanism is configured to control the first supply valve to start providing the first supply material to the supply unit set when or after the first end of the substrate moves relative to the reactor in a first direction to overlap a first portion of the reactor.

4. The apparatus of claim 3, wherein the control mechanism is further configured to control the first supply valve to start providing the first supply material to the supply unit set when or after the second end of the substrate moves relative to the reactor in a second direction to overlap a second portion of the reactor, wherein the second direction is opposite to the first direction.

5. The apparatus of claim 2, wherein the control mechanism is configured to control the first supply valve to stop providing the first supply material to the supply unit set when or after the second end of the substrate moves relative to the reactor in a first direction past a portion of the reactor and when the first end of the substrate does not overlap the reactor.

6. The apparatus of claim 5, wherein the control mechanism is further configured to control the first supply valve to start providing the first supply material to the supply unit set when or after the second end of the substrate moves relative to the reactor in a second direction to overlap the portion of the reactor, wherein the second direction is opposite to the first direction.

7. The apparatus of claim 2, wherein the control mechanism is configured to control the first supply valve to stop providing the first supply material to the supply unit set when the second end of the substrate overlaps a portion of the reactor and when the first end of the substrate does not overlap the reactor.

8. The apparatus of claim 1,
wherein the reactor further comprises a suction unit set configured to suction a least a first residual material from a chamber, and
wherein the control mechanism is further configured to control whether the suction unit set suctions the first residual material from the chamber according to the position of the substrate with respect to the reactor.

9. The apparatus of claim 8, further comprising a pump connected to the suction unit set, wherein the control mechanism is configured to turn off the pump to prevent the suction unit set from performing suction when a first end of the substrate overlaps the reactor and when a second end of the substrate does not overlap the reactor.

10. The apparatus of claim 9, wherein the control mechanism is configured to turn off the pump when or after the first end of the substrate moves relative to the reactor in a first direction to overlap a portion of the reactor.

11. The apparatus of claim 10, wherein the control mechanism is further configured to turn on the pump when or after the first end of the substrate moves relative to the reactor in a second direction past the portion of the reactor, wherein the second direction is opposite to the first direction.

12. The apparatus of claim 9, wherein the control mechanism is configured to turn on the pump to enable the suction unit set to suction the first residual material when or after the second end of the substrate moves relative to the reactor in a first direction past a portion of the reactor and when the first end of the substrate does not overlap the reactor.

13. The apparatus of claim 12, wherein the control mechanism is further configured to turn off the pump when or after the second end of the substrate moves relative to the reactor in a second direction to overlap the portion of the reactor and when the first end of the substrate does not overlap the reactor, wherein the second direction is opposite to the first direction.

14. The apparatus of claim 9, wherein the control mechanism is configured to turn on the pump to enable the suction unit set to suction the first residual material when the second end of the substrate overlaps a portion of the reactor and when the first end of the substrate does not overlap the reactor.

15. The apparatus of claim 8,
wherein the supply unit set comprises a first supply unit for supplying a first supply material, a second supply unit for supplying a second supply material, and a third supply unit for supplying a purge gas,
wherein the third supply unit is disposed between the first supply unit and the second supply unit,
wherein the suction unit set comprises a first suction unit and a second suction unit,
wherein the first suction unit is disposed between the first supply unit and the third supply unit and is configured to suction a first portion of the first residual material, and
wherein the second suction unit is disposed between the second supply unit and the third supply unit and is configured to suction a second portion of the first residual material.

16. An apparatus for forming a material layer on a substrate, the apparatus comprising:
a chamber configured to contain the substrate;
a reactor that comprises a supply unit set and a suction unit set, the supply unit set being configured to supply at least a first supply material to the substrate, the suction unit set being configured to suction a least a first residual material from the chamber; and
a control mechanism configured to start supply of the first supply material to the supply unit set when or after a first end of the substrate moves relative to the reactor in a direction to overlap the reactor and when a second end of the substrate does not overlap the reactor, the control mechanism further configured to stop the suction unit set from performing suction when or after the first end of the substrate moves relative to the reactor in the direction to overlap the reactor and when the second end of the substrate does not overlap the reactor.

17. A method for forming a material layer on a substrate, the method comprising:
performing relative movement between the substrate and a reactor; and
controlling whether to supply a first supply material to the substrate according to a position of the substrate with respect to the reactor.

18. The method of claim 17, further comprising:
starting supplying the first supply material to the substrate when or after a first end of the substrate moves relative to the reactor in a first direction to overlap a first portion of the reactor and when a second end of the substrate does not overlap the reactor; and
stop supplying the first supply material to the substrate when or after the second end of the substrate moves relative to the reactor in the first direction past a second portion of the reactor and when the first end of the substrate does not overlap the reactor.

19. The method of claim 18, further comprising:
starting supplying the first supply material to the substrate when or after the second end of the substrate moves relative to the reactor in a second direction to overlap the second portion of the reactor and when the first end of the substrate does not overlap the reactor, wherein the second direction is opposite to the first direction; and
stop supplying the first supply material to the substrate when or after the first end of the substrate moves relative to the reactor in the second direction past the first portion of the reactor and when the second end of the substrate does not overlap the reactor.

20. The method of claim 18, further comprising:
supplying the first supply material into a chamber that contains the substrate; and
starting suctioning a first residual material from the chamber when or after the second end of the substrate moves relative to the reactor in the first direction past the second portion of the reactor and when the first end of the substrate does not overlap the reactor.
